(19) United States
(12) Patent Application Publication
(10) Pub. No.: US 2002/0080582 A1
(43) Pub. Date: Jun. 27, 2002

(54) Heat pipe heat dissipating device

(76) Inventor: Kai-Cheng Chang, Taipei (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 09/747,994

(22) Filed: Dec. 27, 2000

(51) Int. Cl. H05K 7/20

(52) U.S. Cl. 361/700

(57) ABSTRACT

A heat pipe heat dissipating device comprises a heat pipe and a retainer. The heat pipe is upright with respect to a heat source. The bottom of the heat pipe is in contact with the heat source. An annular edge is installed near a lower end of a periphery of the heat pipe. The retainer is extended with an inner edge and is positioned to an annular edge of the heat pipe. The retainer further has at least one connecting piece for being connected and fixed to the heat source. The heat dissipating element is a transverse radiating fin, or an upright radiator or an upright heat dissipating piece. A wind guiding mask is connected at an outer side of the heat pipe, and the wind guiding mask is connected to at least one fan.

### FIELD OF THE INVENTION

The present invention relates to a heat pipe heat dissipating device, and especially to a structure using an upright heat pipe as a heat conductor.

### BACKGROUND OF THE INVENTION

The microelectronic device is used widely, especially, a chip as a microprocessor. The faster the speed of the microprocessor, the better the heat processing is necessary. Since a chip must be through several millions of operations within one seconds so that the package of the chip will generate large heat. Therefore, the current central processing units in computers have heat dissipating devices for dissipating heat. When a center processing unit is developed, then a better heat dissipating device is necessary so that the central processing unit has a good effect. Therefore, the heat dissipating device is necessary.

A prior art heat dissipating device is shown in FIG. 1. The shape of the radiator 12 is a square shape for matching the size of the central processing unit 12. Then, the radiator is connected to the buckling block 111 of the retainer 11 of the central processing unit 12 by a combining groove 140 of the buckle 14. Then the heat from the central processing unit is dissipated from the radiator 13. The radiator is a fin type and is made by aluminum extrusion so as to achieve the effect of heat dissipation. Afterward, a fan is added to the radiator. The fan serves to guide air so as to increase the heat dissipation. However, this structure is only used to a PC (personal computer, a desk top computer), but not suitable for a notebook computer for its wide thickness. In order to reduce the thickness, an embedded type fan is formed and a plurality of wind guiding strips at the periphery thereof is used as to reduce the heat dissipating effect. Moreover, a large defect occurs, an axial fan guide guides air from an upper side. When cool air flows downwards, the air will collide the contact surface between the guide structure and the fan. The airflow will be interfered between blades. That is to say that the prior art radiator only solves part of the problem of heat dissipation.

### SUMMARY OF THE INVENTION

Accordingly, the primary object of the present invention is to provide a heat pipe heat dissipating device which dissipates heat directly. The prior art radiators dissipates heat indirectly since heat transferring type is used in the current radiators. Namely, a heat conductor is installed on the heat source and then is connected to a heat conductive piece with a heat pipe. Then, by another end of the heat pipe, heat is transferred out of the heat source. Most of the heat pipes are arranged transversely, but this way is not suitable for high conduction. Therefore, in the present invention, a heat pipe with a large diameter is used, that is, the heat pipe is directly contacted to the heat source for transferring heat from the heat source so that the heat pipe of the present invention has dual effects. This is a biggest different of the present invention from the prior art. Furthermore, the heat pipe of the present invention is fixed by retainers to the heat source or other peripherals. The heat source effect is enhanced by further adding other heat dissipating element or element for guiding hot air.

To achieve the object, the present invention provides a heat pipe heat dissipating device comprising a heat pipe and a retainer. The heat pipe upright with respect to a heat source. The bottom of the heat pipe is in contact with the heat source. An annular edge is installed near a lower end of a periphery of the heat pipe. The retainer is extended with an inner edge and is positioned to an annular edge of the heat pipe. The retainer further has at least one connecting piece for being connected and fixed to the heat source. The heat dissipating element is a transverse radiating fin, or an upright radiator or an upright heat dissipating piece. A wind guiding mask is connected at an outer side of the heat pipe, and the wind guiding mask is connected to at least one fan.

The various objects and advantages of the present invention will be more readily understood from the following detailed description when read in conjunction with the appended drawing.

### BRIEF DESCRIPTION OF THE DRAWINGS

FIG. 1 is an exploded perspective view of a prior art.

FIG. 2 is a perspective view of the present invention.

FIG. 3 is an exploded perspective view of the present invention.

FIG. 4 is a lateral view showing the assembly of the present invention.

FIG. 5 is a bottom view of another embodiment of the retainer in the present invention.

FIG. 6 is a perspective view of a first embodiment showing that the present invention is added with a heat dissipating element.

FIG. 7 is a cross sectional view of a first embodiment showing that the present invention is added with a heat dissipating element.

FIG. 8 is a cross sectional view of a second embodiment showing that the present invention is added with a heat dissipating element.

FIG. 9 is a cross sectional view of a third embodiment showing that the present invention is added with a heat dissipating element.

FIG. 10 is a cross sectional view of a fourth embodiment showing that the present invention is added with a heat dissipating element.

### DETAILED DESCRIPTION OF THE PREFERRED EMBODIMENTS

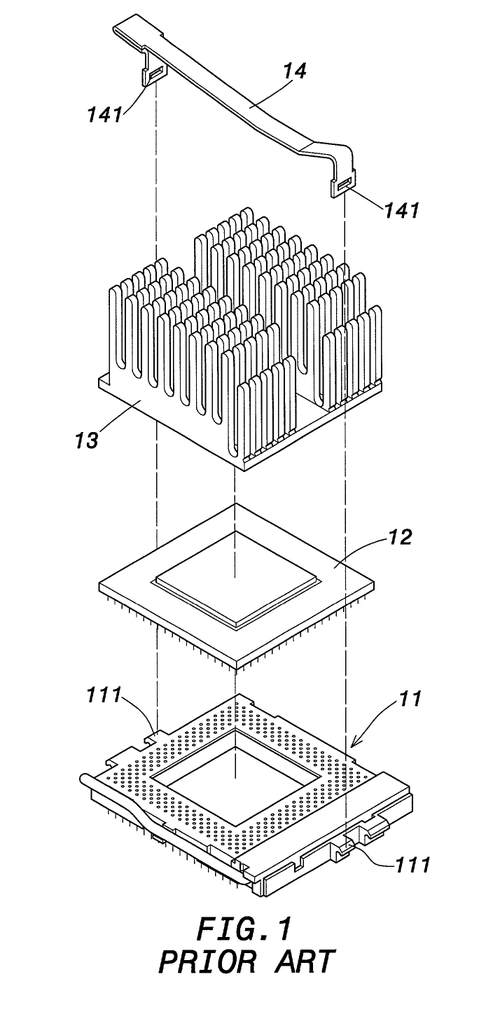

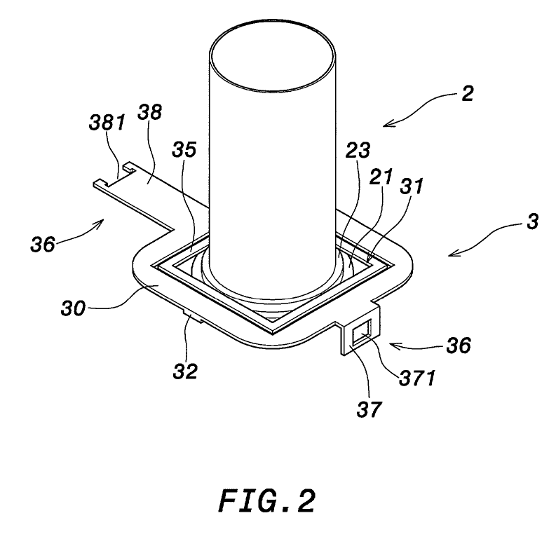

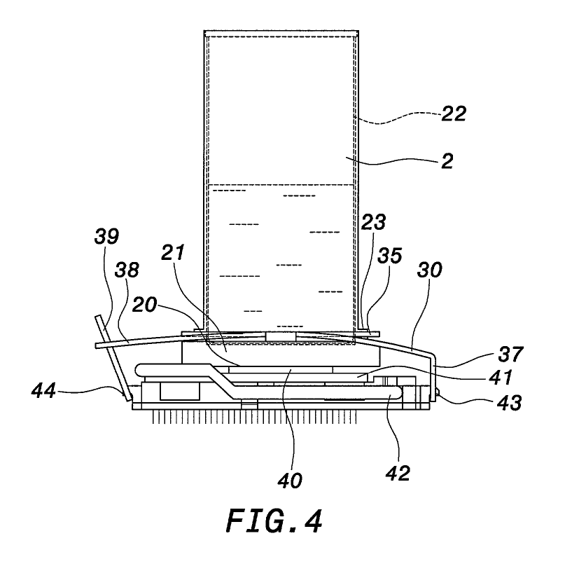

Referring to FIGS. 1 to 10, the heat pipe heat dissipating device of the present invention is illustrated. The basic structure of the heat pipe heat dissipating device may refer to FIGS. 2 to 4. The heat pipe heat dissipating device has a heat pipe 2 and a retainer 3. The heat pipe 2 is upright to the respective heat source 4. The heat source 4 shown in the drawing is a central processing unit 41. The heat source 4 is not confined to that kind of electronic elements, any device dissipating large amount of heat in a high speed is suitable to be used with the heat pipe 2 of the present invention. The heat pipe 2 in the present invention is mainly matched to the size of the present invention. It can be wider or thinner. For example, the P III processor has a width of 25 mm, and the diameter of the heat pipe 2 is 25 mm. Thus, a preferred covering and heat dissipation may be acquired. Therefore, a bottom 20 of the heat pipe 2 serves to be in contact with the surface 40 of the heat source 4. The periphery of the heat pipe 2 near the lower end is installed with an annular edge 21. The inner peripheral surface and the bottom of the heat pipe 2 is installed with a wick structure 22, as the dashed line shown in FIG. 4 so that heat can be dissipated more successfully.

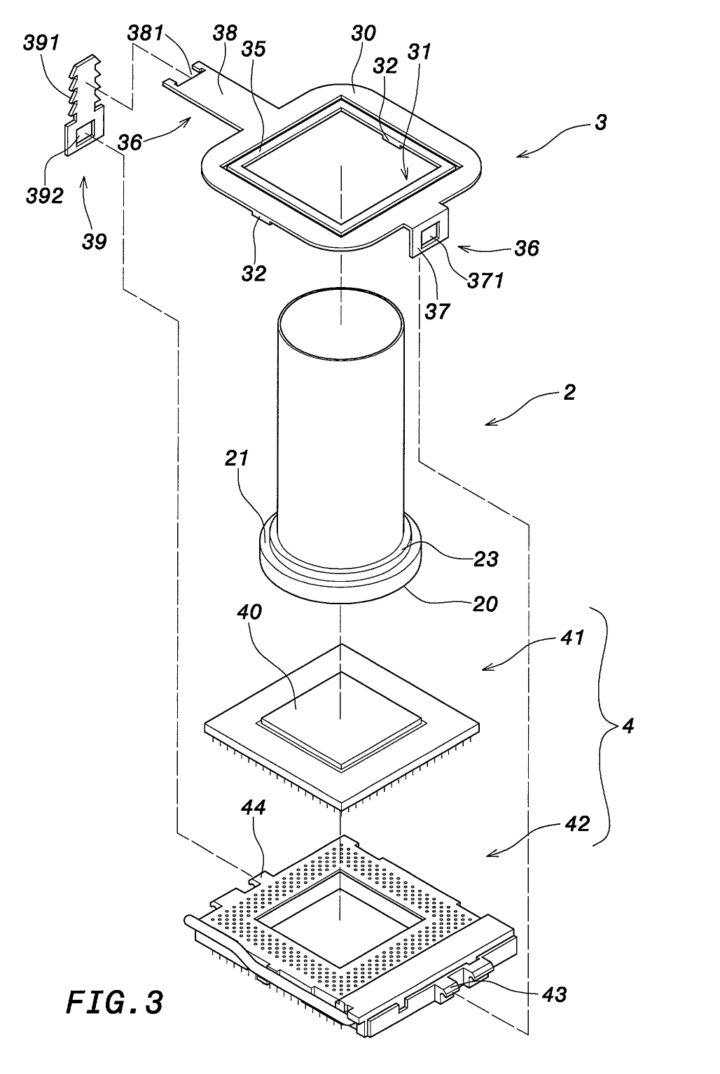

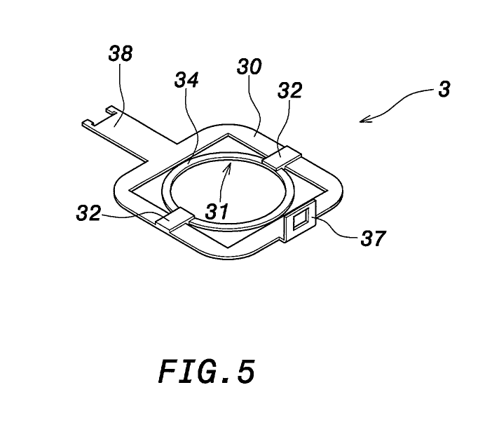

An inner edge 31 of the retainer 3 is positioned to the annular edge 21. The inner edge 31 may be a pair of protrusions or an annular portion. The inner edge 31 is engaged to and fixes the heat pipe 2. The retainer 3 has at least one protruded inner edge 31. The inner edge 31 is a protruding piece 32. The inner edge 31 protruded from the retainer 3 is connected to a cambered piece or a ring piece 34 at an outer edge of the protruding piece 32, as shown in FIG. 5. The inner edge of the retainer 3 is connected to a frame 35 at an outer end of the protruding piece 32, as shown in FIG. 3.

At least one connecting piece 36 extended from the retainer 3 is fixed to the heat source 4 or a periphery of the heat source 4. For example, in the aforesaid central processing unit, no position in the central processing unit may be used as a fixed point since the process 41 is a package chip and is connected to a retaining seat 42 by pins. The prior art various radiator is fixed to the retaining seat 42 or a circuit board. The connecting pieces 36 are extended from two sides of the retainer 3. As shown in FIG. 3, the connecting pieces are different at two sides, but in other embodiment, they may be symmetric at two sides, such as a first strip and a second strip. A first strip 37 is extended from one side and then at a distal end of the first strip 37 is formed with a first hole 371. The first hole 371 is buckled to the first protrusion 43 at the periphery of the retaining seat 42. Another side of the second strip 38 is extended from another side of the connecting piece 36. A dovetail groove 381 is installed at a distal end of the second strip 38. There is a buckle 39. Two sides of the upper end of the buckle 39 has teeth for adjusting combining position so as to be connected to the dovetail groove 381. The lower end of the buckle 39 is connected to a second hole 391. The second hole 391 is buckled to a second protrusion 44 at a periphery of the retaining seat 42.

The aforesaid combination way is only one way of the connecting piece, however, the type of the connecting piece is not confined to the aforesaid structure, it may be a pivotal buckle or an integral formed elastomer or a hook. All these may be used as examples of the present invention. The inner edge 31 can be directly connected to the connecting piece 36, as the combination illustrated in FIG. 4. At two sides of the outer edge 30 of the retainer 3, each inner edge 31 is as a center, and from the connecting piece 36 it is bent towards two sides so as to complete the operation of buckling.

In the assembly of the present invention, it is only necessary to buckle the heat pipe to the heat source so that the heat pipe is upright from the heat dissipating device above the heat source. Since the heat pipe is made of copper with a good conductivity. The heat pipe has a better convection and a good heat conductor. Thus, it has dual effects of heat convection and heat dissipating.

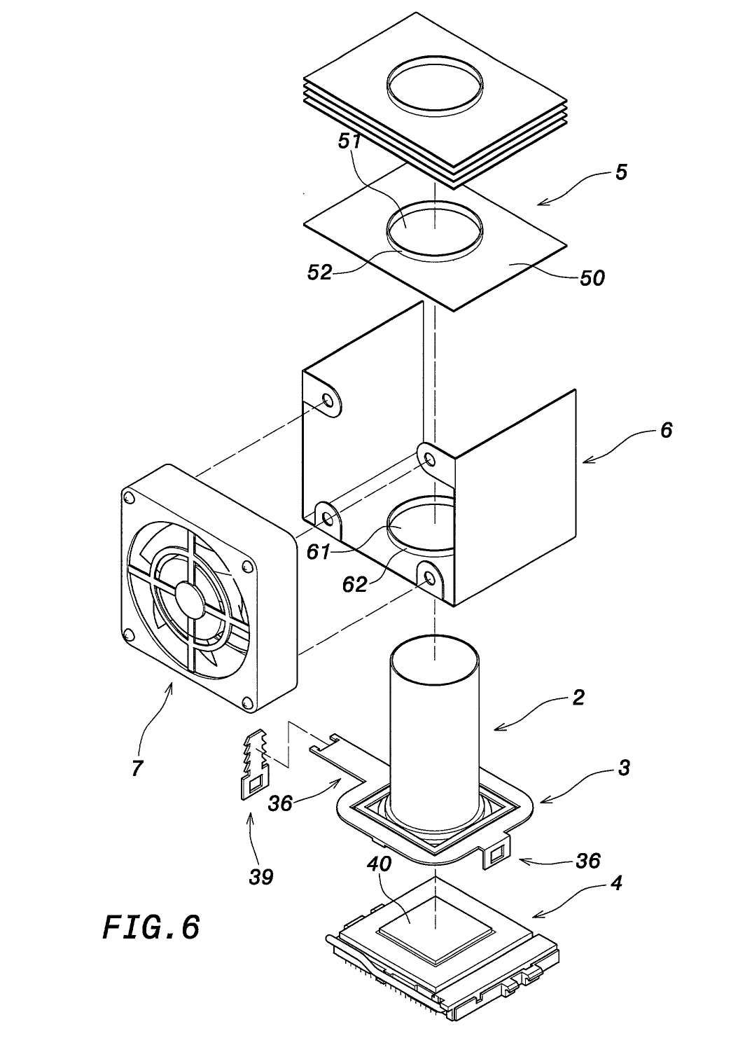

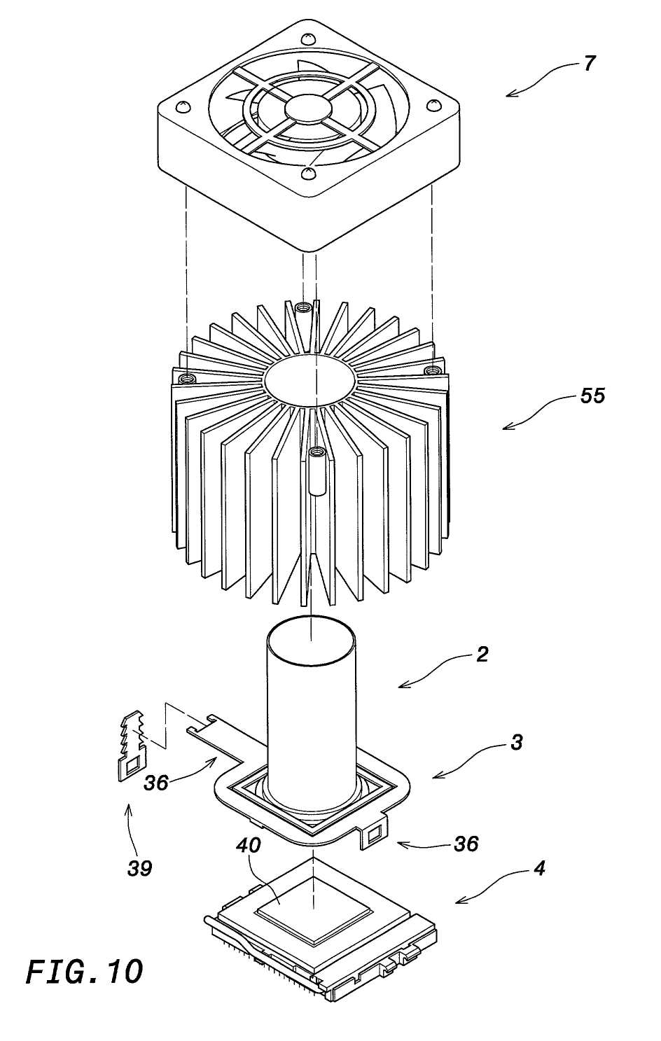

A periphery of the heat pipe 2 is enclosed by the heat dissipating element 5. The heat dissipating element 5 is a transverse radiating fins 50, as shown in FIG. 6. The heat dissipating element 5 may an upright radiator 55 or an upright heat dissipating piece, as shown in FIG. 10, which is a radiating heat dissipating structure and is presented by a radiator and a solid structure. The heat dissipating piece is folded from a plate. A wind guiding mask 6 can be connected to the heat dissipating element 5. At least one fan 7 can be connected to the heat pipe 2 or outside of the heat dissipating element 5 or the wind guiding mask 6.

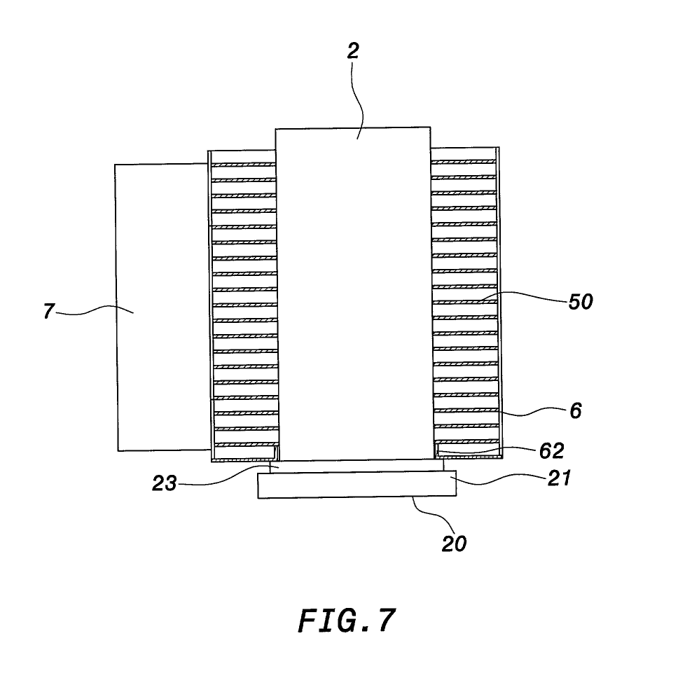

A fan 7 is installed out of the heat pipe 2 for blowing wind to the heat pipe 2 or exhausting wind. Furthermore, referring to FIG. 7, a lateral side of the wind guiding mask 6 is connected with a fan 7, or a radiating fin 50 is connected within the wind guiding mask 6.

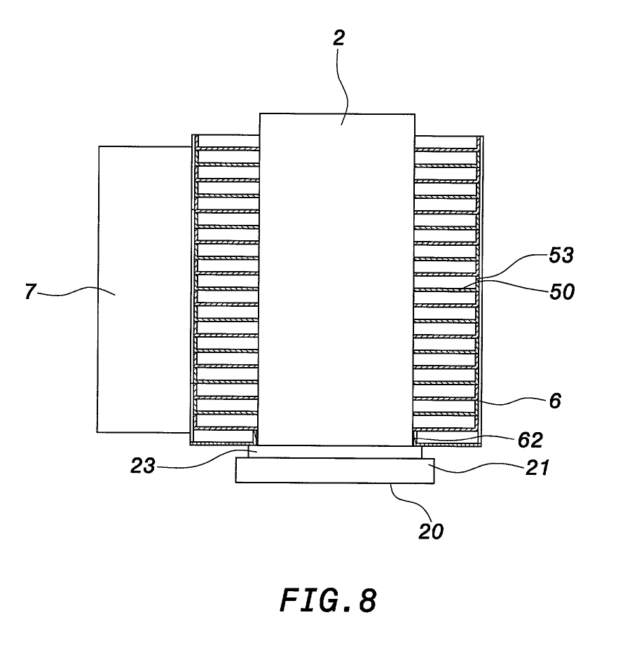

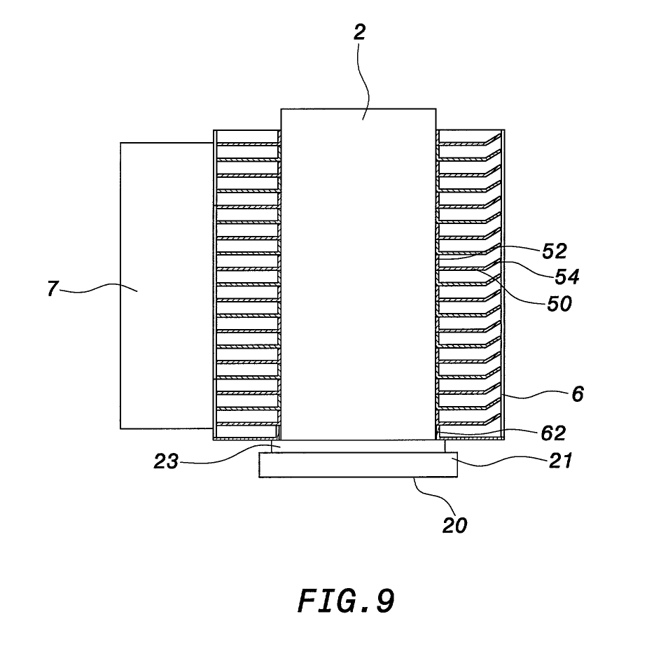

The radiating fin 50 is placed transversely, as shown in FIG. 9. The radiating fin 50 can be directly connected to the heat pipe 2 or is buckled out of the heat pipe by a set structure, such as an aluminum piece. If a heat pipe made of copper is used, the heat pipe can be expanded so as to be connected to the aluminum made radiating fin. Thus, the assembly work is complete. Furthermore, the radiating fin may be welded to the heat pipe, in general, copper piece is used in welding. The radiating fin 50 is a thin piece capable of being connected to the heat pipe. A round hole 51 is formed at a respective position. An inner edge of the round hole 51 is connected with a protruded annular edge 52 or an outer annular edge 53 which can be folded through 90 degrees, as shown in FIG. 8. Thereby, the radiating fin 50 can be stacked conveniently. In application, the wind guiding mask may be not to be installed with aforesaid two types of heat pipes. Furthermore, one side of the radiating fin 50 has a folded edge 54 which is beneficial to the flow of air, as shown in FIG. 9.

The wind guiding mask 6 has a U shape, as shown in FIG. 6. The bottom thereof is has a round hole 61. The round hole 61 has an inner annular protruded edge 62. An opening at one lateral side is installed with ears 63 for fixing a fan. A bearing edge 23 is installed above the annular edge 21 of the heat pipe 2 for positioning the wind guiding mask 6. The fan 7 may be an axial flow fan or an eccentric fan, etc. The fan may have an operation way of wind extraction and exhausting.

In the aforesaid structure, in the present invention, by an upright combination way, the heat source can be fixed. The heat pipe is pivotally connected to the retainer and thus, the heat pipe is rotatable, and of course, the heat dissipating element also rotates therewith. In the present invention, the fixing way is different from the prior art way. Furthermore, the direction of heat dissipation is selectable, however, this can not be achieved by the prior art. The heat pipe of the present invention can be matched with various heat dissipating elements, and thus, the heat pipe of the present invention has a preferred heat dissipation device. More important, the present invention conducts heat directly. Heat from the heat source is transferred directly through the heat pipe. The heat pipe is not only a heat conductor, but also a heat dissipating device. In the assembly, it is only necessary to match the positioning of a retainer. Therefore, the present invention provides a good utility and thus, it has a structure different from the prior art.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A heat pipe heat dissipating device comprising:
a heat pipe upright with respect to a heat source; a bottom of the heat pipe being in contact with the heat source; an annular edge being installed near a lower end of a periphery of the heat pipe; and
a retainer extended with an inner edge and being positioned to an annular edge of the heat pipe; the retainer further having at least one connecting piece for being connected and fixed to the heat source.

2. The heat pipe heat dissipating device as claimed in claim 1, wherein an inner periphery and an inner bottom of the heat pipe are installed with a wick structure.

3. The heat pipe heat dissipating device as claimed in claim 1, wherein at least one fan is connected to an outer side of the heat pipe.

4. The heat pipe heat dissipating device as claimed in claim 1, wherein a wind guiding mask is connected at an outer side of the heat pipe, and the wind guiding mask is connected to at least one fan.

5. The heat pipe heat dissipating device as claimed in claim 1, wherein a periphery of the heat pipe is engaged with a heat dissipating element.

6. The heat pipe heat dissipating device as claimed in claim 5, wherein the heat dissipating element is connected with at least one fan.

7. The heat pipe heat dissipating device as claimed in claim 5, wherein a wind guiding mask is connected at an outer side of the heat dissipating element and the wind guiding mask is connected to at least one fan.

8. The heat pipe heat dissipating device as claimed in claim 5, wherein the heat dissipating element is a transverse radiating fin, or an upright radiator or an upright heat dissipating piece.

9. The heat pipe heat dissipating device as claimed in claim 1, wherein the retainer is fixed to the annular edge by at least one protruded inner edge; the connecting piece has two sides, each side is extended with a buckle for being fixed to the heat source, an inner edge of the retainer is connected to an outer edge and the outer edge is connected to the connecting piece; at two sides of the outer edge of the retainer, each inner edge is used as a center, and from the connecting piece it is bent towards two sides.
